(19) United States
(12) Patent Application Publication
(10) Pub. No.: US 2015/0162438 A1
(43) Pub. Date: Jun. 11, 2015

(54) MEMORY DEVICE EMPLOYING AN INVERTED U-SHAPED FLOATING GATE

(71) Applicant: International Business Machines Corporation, Armonk, NY (US)

(72) Inventors: Anthony I. Chou, Beacon, NY (US); Murshed M. Chowdhury, Newburgh, NY (US); Arvind Kumar, Chappaqua, NY (US)

(73) Assignee: International Business Machines Corporation, Armonk, NY (US)

(21) Appl. No.: 14/102,829

(22) Filed: Dec. 11, 2013

(51) Int. Cl. H01L 29/788; H01L 29/66; H01L 29/423; H01L 21/3105; H01L 21/28; H01L 21/3213; H01L 21/02; H01L 29/78; H01L 29/06

(52) U.S. Cl. CPC H01L 29/788; H01L 29/7851; H01L 29/66825; H01L 29/66795; H01L 29/42324; H01L 29/0653; H01L 29/42364; H01L 29/42376; H01L 21/28273; H01L 21/32133; H01L 21/32139; H01L 21/02233; H01L 21/02282; H01L 21/02164; H01L 21/31055

(57) ABSTRACT

A tunneling dielectric layer, a floating gate material layer, and an etch stop layer are formed over a semiconductor fin. After formation of a planarization dielectric layer, a top surface of the floating gate material layer is physically exposed above the semiconductor fin by removing a horizontal portion of the etch stop layer. After removal of the planarization dielectric layer, a semiconductor oxide portion is formed on a horizontal portion of the floating gate material layer. After removal of the etch stop layer, the floating gate material layer is patterned into a floating gate electrode employing the semiconductor oxide portion as a self-aligned etch mask. A control gate dielectric layer and a conductive material layer are deposited and patterned to form a control gate dielectric and a gate electrode.

### BACKGROUND

The present disclosure relates to a flash memory device employing an inverted U-shaped floating gate and methods of manufacturing the same.

Due to three-dimensional geometry of fin field effect transistors, conventional methods to form self-aligned floating gates do not work with fin field effect transistors. Thus, split gate structures or non-self-aligned floating gates are typically employed to form a non-volatile memory employing a fin field effect transistor. Split gate methods are not compatible with known integrations schemes for forming triple gate fin field effect transistors that allow three-sided channels, i.e., a horizontal channel on the top surface and a pair of vertical channels on sidewalls of the semiconductor fin. Non-self-aligned structures depend on lithographic overlay tolerances to avoid electrical shorts, and thus, making it difficult to form a high density memory structure.

### SUMMARY

A tunneling dielectric layer, a floating gate material layer, and an etch stop layer are formed over a semiconductor fin. After formation of a planarization dielectric layer, a top surface of the floating gate material layer is physically exposed above the semiconductor fin by removing a horizontal portion of the etch stop layer. After removal of the planarization dielectric layer, a semiconductor oxide portion is formed on a horizontal portion of the floating gate material layer. After removal of the etch stop layer, the floating gate material layer is patterned into a floating gate electrode employing the semiconductor oxide portion as a self-aligned etch mask. A control gate dielectric layer and a conductive material layer are deposited and patterned to form a control gate dielectric and a control gate electrode, respectively.

According to an aspect of the present disclosure, a semiconductor structure includes a semiconductor fin located on a substrate, an inverted U-shaped tunneling gate dielectric located on the semiconductor fin, a floating gate electrode having an inverted U-shape and contacting the inverted U-shaped tunneling gate dielectric, a control gate dielectric contacting a top surface and outer sidewalls of the floating gate electrode, and a control gate electrode overlying the control gate dielectric.

According to another aspect of the present disclosure, a method of forming a semiconductor structure is provided. A semiconductor fin is formed on a substrate. An inverted U-shaped tunneling gate dielectric is formed on the semiconductor fin. A floating gate electrode having an inverted U-shape is formed on the inverted U-shaped tunneling gate dielectric. A control gate dielectric is formed on a top surface and outer sidewalls of the floating gate electrode. A control gate electrode is formed over the control gate dielectric.

### BRIEF DESCRIPTION OF THE SEVERAL VIEWS OF THE DRAWINGS

FIG. 1A is a top-down view of a first exemplary semiconductor structure after formation of semiconductor fins according to a first embodiment of the present disclosure.

FIG. 1B is a vertical cross-sectional view of the first exemplary semiconductor structure along the vertical plane B-B′ of FIG. 1A.

FIG. 2A is a top-down view of the first exemplary semiconductor structure after formation of a shallow trench isolation structure and tunneling dielectric layers according to the first embodiment of the present disclosure.

FIG. 2B is a vertical cross-sectional view of the first exemplary semiconductor structure along the vertical plane B-B′ of FIG. 2A.

FIG. 3A is a top-down view of the first exemplary semiconductor structure after formation of a floating gate material layer and an etch stop layer according to the first embodiment of the present disclosure.

FIG. 3B is a vertical cross-sectional view of the first exemplary semiconductor structure along the vertical plane B-B′ of FIG. 3A.

FIG. 4A is a top-down view of the first exemplary semiconductor structure after deposition and planarization of a planarization dielectric layer according to the first embodiment of the present disclosure.

FIG. 4B is a vertical cross-sectional view of the first exemplary semiconductor structure along the vertical plane B-B′ of FIG. 4A.

FIG. 5A is a top-down view of the first exemplary semiconductor structure after removal of physically exposed horizontal portions of the etch stop layer according to the first embodiment of the present disclosure.

FIG. 5B is a vertical cross-sectional view of the first exemplary semiconductor structure along the vertical plane B-B′ of FIG. 5A.

FIG. 6A is a top-down view of the first exemplary semiconductor structure after removal of the planarization dielectric layer according to the first embodiment of the present disclosure.

FIG. 6B is a vertical cross-sectional view of the first exemplary semiconductor structure along the vertical plane B-B′ of FIG. 6A.

FIG. 7A is a top-down view of the first exemplary semiconductor structure after formation of semiconductor oxide portions by conversion of surface portions of the floating gate material layer according to the first embodiment of the present disclosure.

FIG. 7B is a vertical cross-sectional view of the first exemplary semiconductor structure along the vertical plane B-B′ of FIG. 7A.

FIG. 8A is a top-down view of the first exemplary semiconductor structure after removal of the etch stop layer and definition of floating gate electrodes by an anisotropic etch that employs the semiconductor oxide portions as an etch mask according to the first embodiment of the present disclosure.

FIG. 8B is a vertical cross-sectional view of the first exemplary semiconductor structure along the vertical plane B-B′ of FIG. 8A.

FIG. 9A is a top-down view of the first exemplary semiconductor structure after removal of the semiconductor oxide portions by an anisotropic etch according to the first embodiment of the present disclosure.

FIG. 9B is a vertical cross-sectional view of the first exemplary semiconductor structure along the vertical plane B-B′ of FIG. 9A.

FIG. 10A is a top-down view of the first exemplary semiconductor structure after formation of a control gate dielectric, a gate electrode, a gate spacer, and source and drain regions according to the first embodiment of the present disclosure.

FIG. 10B is a vertical cross-sectional view of the first exemplary semiconductor structure along the vertical plane B-B′ of FIG. 10A.

FIG. 11A is a top-down view of a first variation of the first exemplary semiconductor structure according to the first embodiment of the present disclosure.

FIG. 11B is a vertical cross-sectional view of the first variation the first exemplary semiconductor structure along the vertical plane B-B′ of FIG. 11A.

FIG. 12A is a top-down view of a second variation of the first exemplary semiconductor structure according to the first embodiment of the present disclosure.

FIG. 12B is a vertical cross-sectional view of the second variation the first exemplary semiconductor structure along the vertical plane B-B′ of FIG. 12A.

FIG. 13A is a top-down view of a second exemplary semiconductor structure after formation of semiconductor oxide portions by selective deposition of a semiconductor oxide material according to the first embodiment of the present disclosure.

FIG. 13B is a vertical cross-sectional view of the second exemplary semiconductor structure along the vertical plane B-B′ of FIG. 13A.

FIG. 14A is a top-down view of the second exemplary semiconductor structure after formation of a control gate dielectric, a gate electrode, a gate spacer, and source and drain regions according to the first embodiment of the present disclosure.

FIG. 14B is a vertical cross-sectional view of the second exemplary semiconductor structure along the vertical plane B-B′ of FIG. 14A.

### DETAILED DESCRIPTION

As stated above, the present disclosure relates to a flash memory device employing an inverted U-shaped floating gate and methods of manufacturing the same, which are now described in detail with accompanying figures. It is noted that like and corresponding elements mentioned herein and illustrated in the drawings are referred to by like reference numerals. As used herein, ordinals such as “first” and “second” are employed merely to distinguish similar elements, and different ordinals may be employed to designate a same element in the specification and/or claims.

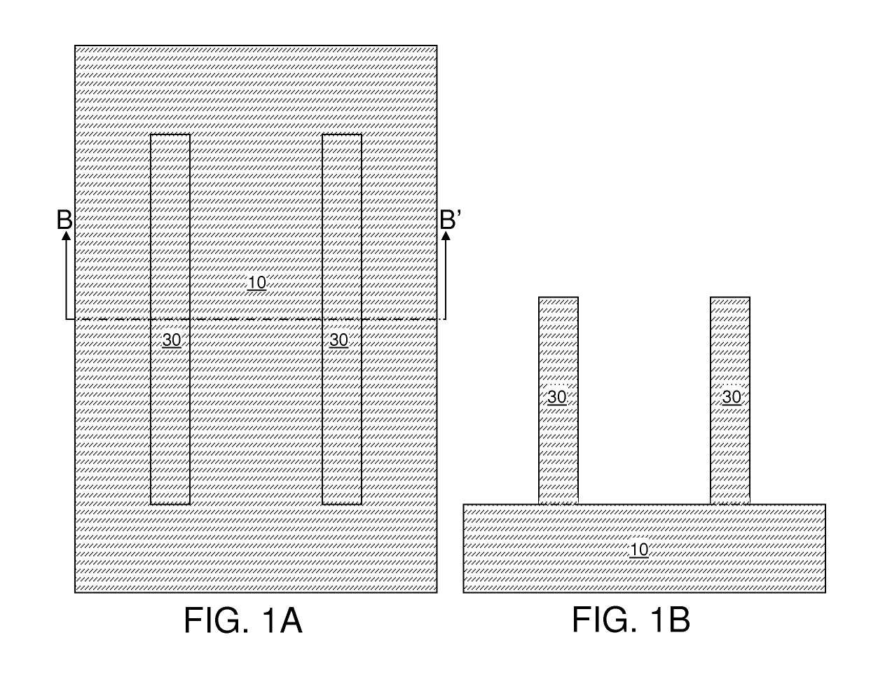

Referring to FIGS. 1A and 1B, a first exemplary structure according to an embodiment of the present disclosure includes semiconductor fins 30 formed on a substrate 10. The semiconductor fins 30 includes a single crystalline semiconductor material such as single crystalline silicon, a single crystalline silicon-germanium alloy, or any other single crystalline semiconductor material on which silicon carbide or a single crystalline silicon carbon alloy having a crystal structure of silicon carbide can be epitaxially deposited. In one embodiment, the semiconductor fins 30 can include single crystalline silicon. As used herein, a “fin” refers to a structure having a pair of sidewalls that are parallel to each other and a combination of a horizontal top surface and a horizontal bottom surface. As used herein, a “semiconductor fin” refers to a fin consisting of at least one semiconductor material.

In one embodiment, the semiconductor fins 30 can be formed by providing a bulk semiconductor substrate such as a single crystalline silicon substrate, and by patterning the top portion of the bulk semiconductor substrate. In this case, the remaining portion of the semiconductor substrate constitutes the substrate 10 underlying the semiconductor fins 30. The semiconductor fins 30 are adjoined to the substrate 10, which can include the same semiconductor material as the semiconductor fins 30.

In another embodiment, the semiconductor fins 30 can be formed by providing a semiconductor-on-insulator (SOI) substrate including a top semiconductor layer, a buried insulator layer, and a handle substrate, and by patterning the top semiconductor layer. In this case, the remaining portions of the top semiconductor layer after patterning can be semiconductor fins.

In one embodiment, the patterning of the semiconductor fins 30 can be performed by applying and lithographically patterning a photoresist layer and subsequently transferring the pattern in the photoresist layer into the top portion of the bulk semiconductor substrate or into the top semiconductor layer of an SOI substrate. In another embodiment, the semiconductor fins 30 can be formed by a sidewall image transfer (SIT) process as known in the art, in which case the width of each semiconductor fin 30 can be a sublithographic dimension, i.e., a dimension less than a critical dimension (which is the minimum lithographic dimension that can be printed by a single lithographic exposure and development).

In one embodiment, a plurality of semiconductor fins 30 can extend along a lengthwise direction and can be parallel to each other. As used herein, a lengthwise direction of an element is a direction that is parallel to an axis of rotation passing through the center of mass of the element and providing the least moment of inertia. As used herein, a widthwise direction of an element is a direction that is horizontal and perpendicular to the lengthwise direction of the element. In case a semiconductor fin is a rectangular parallelepiped, the lengthwise direction of the semiconductor fin is parallel to the direction of the longest edge of the semiconductor fin.

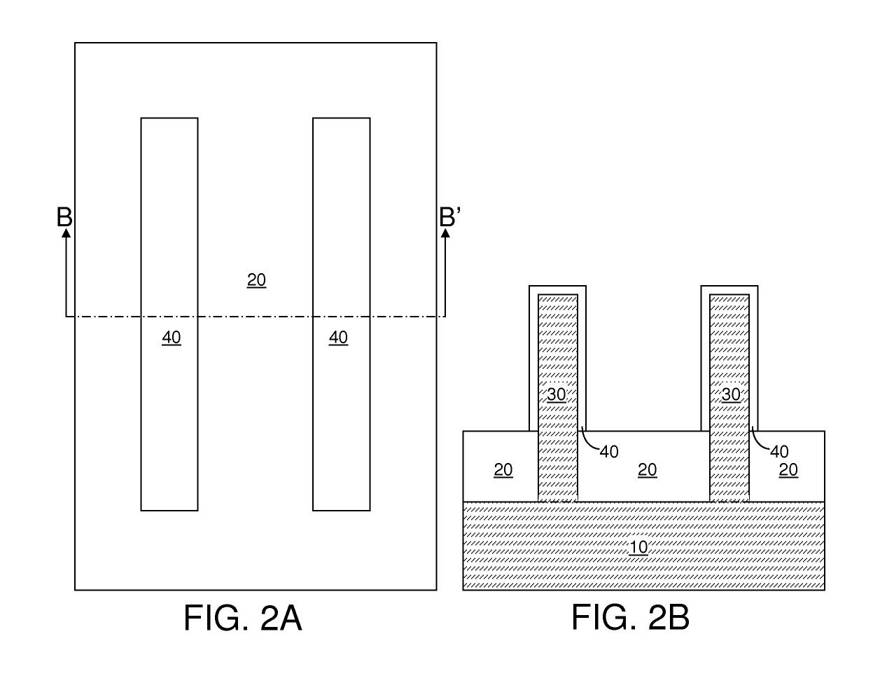

Referring to FIGS. 2A and 2B, a shallow trench isolation layer 20 can be formed around lower portions of the semiconductor fins 30. In one embodiment, a dielectric material such as silicon oxide can be deposited over the semiconductor fins 30 and planarized employing the top surfaces of the semiconductor fins as stopping surfaces. Subsequently, the dielectric material can be recessed to form the shallow trench isolation layer 20. In another embodiment, a self-planarizing dielectric material such as spin-on glass (SOG) can be applied and cured to form the shallow trench isolation layer 20. The shallow trench isolation layer provides electrical isolation between devices formed in neighboring semiconductor fins. A channel stop ion implantation process can be performed to enhance electrical isolation among the semiconductor fins. During the channel stop ion implantation, dopants of the opposite conductivity type as the dopant type of the semiconductor material in the substrate 10 can be implanted into lower portions of the semiconductor fins 30.

In an alternate embodiment, if the semiconductor fins 30 are formed by patterning a top semiconductor layer of an SOI substrate, the buried insulator layer provides electrical isolation between neighboring semiconductor fins 30.

The height of the portion of each semiconductor fin 30 located above the top surface of the shallow trench isolation layer (or above a buried insulator layer if the semiconductor fins are formed from an SOI substrate) can be in a range from 15 nm to 300 nm, although lesser and greater heights can also be employed.

An inverted U-shaped tunneling gate dielectric 40 is formed on each semiconductor fin 30. As used herein, an element is an “inverted U-shaped” structure if the element includes a parallel pair of vertical portions adjoined to each other through a horizontal portion that is adjoined to a topmost portion of each of the parallel pair of vertical portions. The bottom surface of the horizontal portion is raised above a horizontal plane including bottommost surfaces of the parallel pair of vertical portions of the inverted U-shaped structure. As used herein, a “tunneling gate dielectric” refers to a gate dielectric through which charge carriers can tunnel through by quantum tunneling phenomenon as known in the art.

The inverted U-shaped tunneling gate dielectric 40 can include any dielectric material that can be employed as a tunneling gate dielectric known in the art. In one embodiment, the inverted U-shaped tunneling gate dielectrics 40 can include a dielectric material formed by conversion of surface portions of the semiconductor fins 30 into a dielectric material by thermal conversion and/or plasma conversion. For example, the inverted U-shaped tunneling gate dielectrics 40 can include silicon oxide, silicon nitride, silicon oxynitride, or a stack thereof. In one embodiment, the inverted U-shaped tunneling gate dielectrics 40 can be formed by a conformal deposition method (such as low pressure chemical vapor deposition or atomic layer deposition) and/or by a crystallographic-orientation independent conversion process, which can be a thermal oxidation process, a thermal nitridation process, a plasma oxidation process, or a plasma nitridation process. In this case, the thickness of the inverted U-shaped tunneling gate dielectrics 40 can be the same throughout the entirety thereof. Thus, all vertical portions and all horizontal portions of the inverted U-shaped tunneling gate dielectrics 40 can be the same. The thickness of the inverted U-shaped tunneling gate dielectrics 40 can be in a range from 3.0 nm to 10.0 nm, although lesser and greater thicknesses can also be employed.

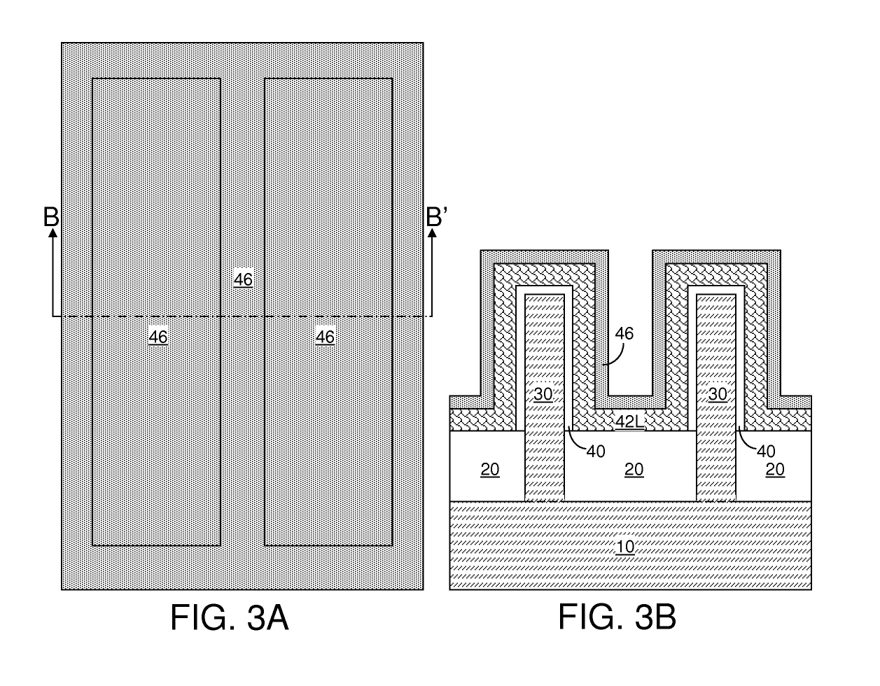

Referring to FIGS. 3A and 3B, a floating gate material layer 42L is deposited on the surfaces of the inverted U-shaped tunneling gate dielectrics 40. The floating gate material layer 42L includes a doped semiconductor material. In one embodiment, the floating gate material layer 42L can include doped polysilicon, a doped silicon-germanium alloy, or a doped silicon-carbon alloy. The floating gate material layer 42L can be deposited by a conformal or non-conformal deposition method. For example, the floating gate material layer 42L can be deposited by chemical vapor deposition (CVD), physical vapor deposition (PVD), atomic layer deposition (ALD), or a combination thereof.

In one embodiment, the floating gate material layer 42L can be deposited by a conformal deposition method such as low pressure chemical vapor deposition (LPCVD) or atomic layer deposition (ALD). In this case, horizontal portions and vertical portions of the floating gate material layer 42L can have the same thickness. The thickness of the floating gate material layer 42L can be in a range from 3 nm to 100 nm, although lesser and greater thicknesses can also be employed.

An etch stop layer 46 is formed on the floating gate material layer 42L. The etch stop layer 46 includes a disposable material that can be employed as an etch stop material during removal of a dielectric material for a planarization dielectric material to be subsequently employed. The disposable material of the etch stop layer 46 is different from the material of the floating gate material layer 42L so that the etch stop layer 46 can be subsequently removed selective to the floating gate material layer 42L. The etch stop layer 46 can include a dielectric material such as a dielectric nitride or a dielectric metal oxide. Alternately, the etch stop layer 46L can include a metallic material such as a conductive metallic nitride or a conductive metallic carbide.

In one embodiment, the disposable material of the etch stop layer 46 can be an oxygen-impermeable material. As used herein, an oxygen-impermeable material refers to a material having permeability for oxygen that is less than 1/10 of the permeability of oxygen of thermal silicon oxide in a temperature range from 500° C. to 1,000° C. For example, the etch stop layer 46 can include silicon nitride.

The etch stop layer 46 can be deposited by a conformal or non-conformal deposition method. For example, the etch stop layer 46 can be deposited by chemical vapor deposition (CVD) or atomic layer deposition (ALD). The thickness of the etch stop layer 46, as measured at a horizontal portion of the etch stop layer 46, can be in a range from 3 nm to 30 nm, although lesser and greater thicknesses can also be employed.

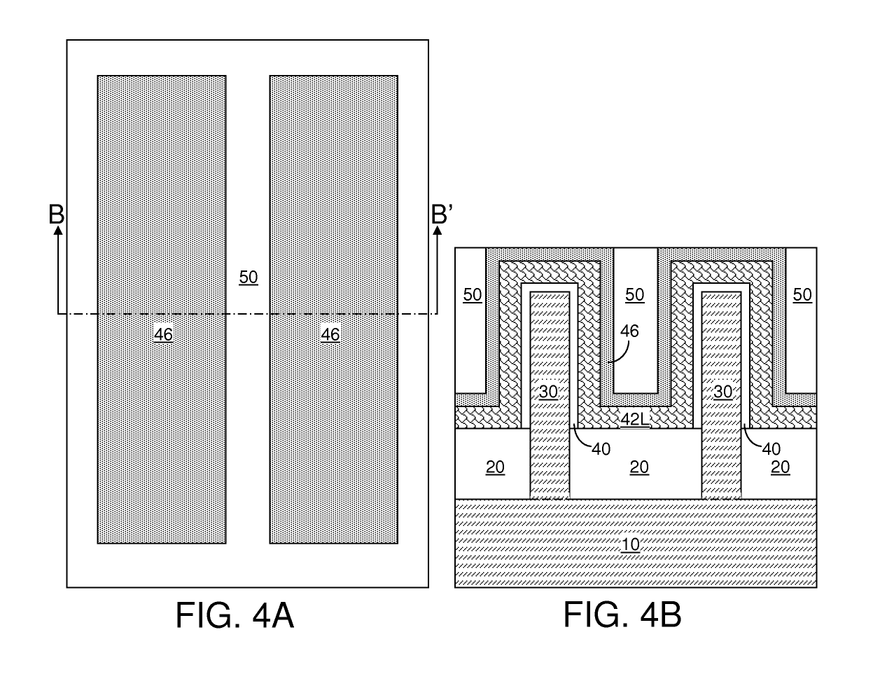

Referring to FIGS. 4A and 4B, a dielectric material can be deposited over the etch stop layer 46. The dielectric material can include silicon oxide or non-porous organosilicate glass (OSG), and can be deposited by chemical vapor deposition (CVD) or spin-coating. The deposited dielectric material can be subsequently planarized employing the topmost surfaces of the etch stop layer 46 as a stopping surface. In one embodiment, the planarization of the deposited dielectric material can be performed by chemical mechanical planarization (CMP). The horizontal portions of the etch stop layer 46 that overlie the semiconductor fins 30 can be employed as a stopping layer during the planarization process. The remaining portion of the deposited dielectric material constitutes a dielectric material layer, which is herein referred to as a planarization dielectric layer 50. The top surface of the planarization dielectric layer 50 can be coplanar with the topmost surfaces of the etch stop layer 46.

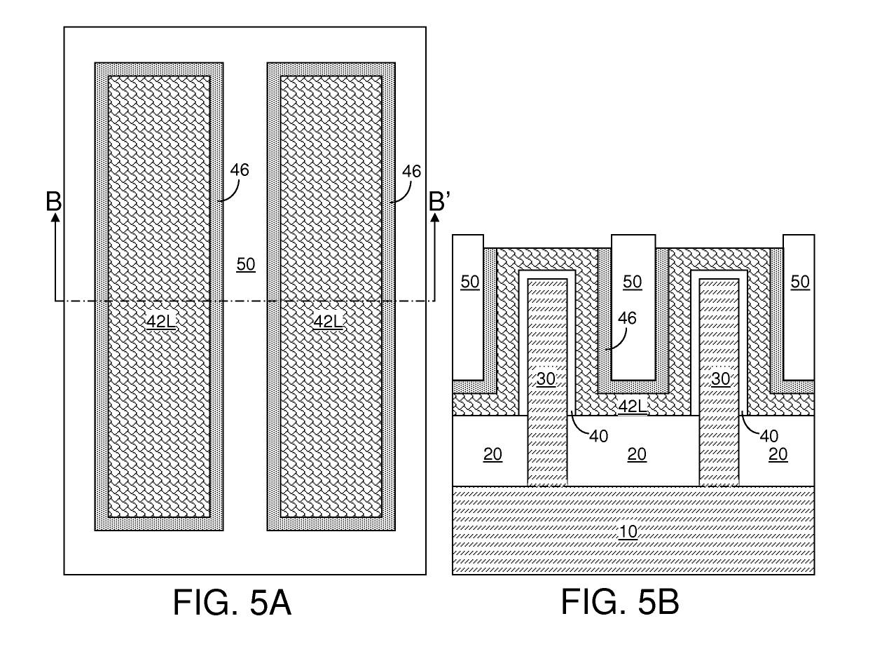

Referring to FIGS. 5A and 5B, physically exposed horizontal portions of the etch stop layer 46 can be removed selective to the floating gate material layer 42L and the planarization dielectric layer 50 by an etch process. The etch process can be a dry etch process or a wet etch process which selectively removes the etch stop layer 46 but does not etch the planarization dielectric layer 50. For example, if the etch stop layer 46 includes silicon nitride, the topmost horizontal portions of the etch stop layer 46 overlying the semiconductor fins 30 can be removed by a wet etch process employing hot phosphoric acid. In this case, the hot phosphoric acid does not significantly etch the planarization dielectric layer 50. A topmost surface of the floating gate material layer 42L is physically exposed above each semiconductor fin 30 by the removal of the physically exposed horizontal portions of the etch stop layer 46.

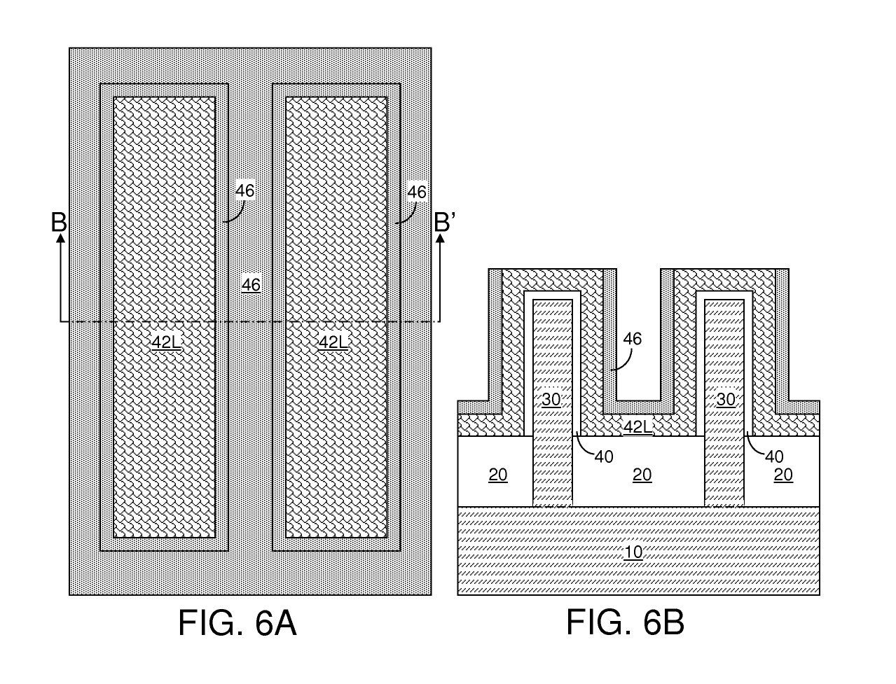

Referring to FIGS. 6A and 6B, the planarization dielectric layer 50 is removed selective to the etch stop layer 46 and the floating gate material layer 42L. The removal of the planarization dielectric layer 50 can be performed by a dry etch or a wet etch. For example, if the planarization dielectric layer 50 includes silicon oxide or organosilicate glass, and if the etch stop layer 46 includes silicon nitride, the removal of the planarization dielectric layer 50 can be performed by a wet etch employing hydrofluoric acid.

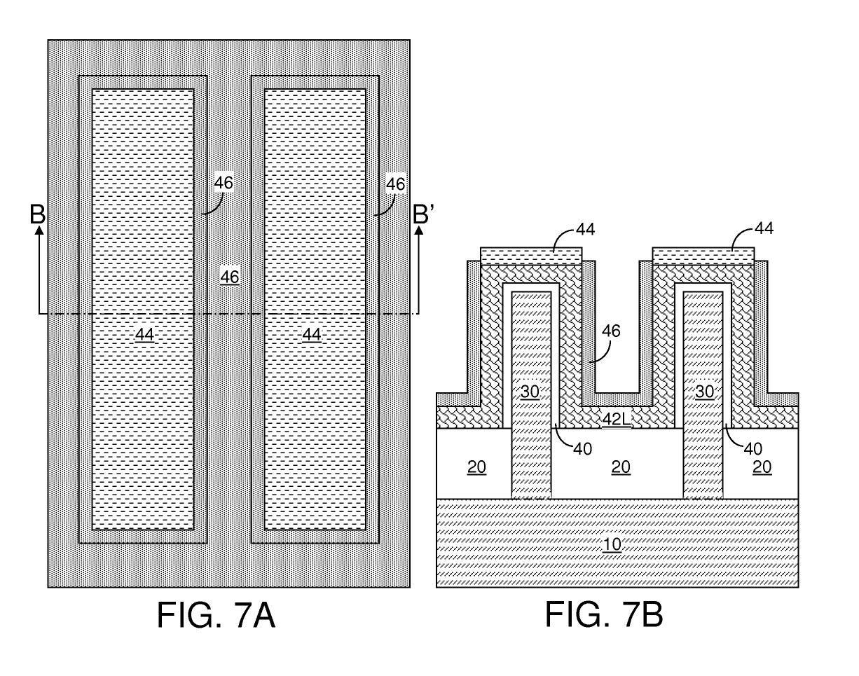

Referring to FIGS. 7A and 7B, semiconductor oxide portions 44 are formed by conversion of physically exposed surface portions of the floating gate material layer 42L. Specifically, the semiconductor oxide portions 44 are formed by oxidation of the semiconductor material in the floating gate material layer 42L while sidewall surfaces of the floating gate material layer 42L are protected by the etch stop layer 46.

In one embodiment, the etch stop layer 46L includes an oxygen-impermeable material, and the oxidation of the floating gate material layer 42L proceeds only at the topmost portions of the floating gate material layer 42L overlying the semiconductor fins 30. The oxidation of the topmost portions of the floating gate material layer 42L can be performed by thermal oxidation, plasma oxidation, or a combination thereof. The thickness of the semiconductor oxide portions 44 can be in a range from 3 nm to 30 nm, although lesser and greater thicknesses can also be employed.

Because the semiconductor material of the floating gate material layer 42L is consumed during formation of the semiconductor oxide portions 44, the thickness of the topmost horizontal portions of the floating gate material layer 42L after formation of the semiconductor oxide portions 44 is less than the thickness of the bottommost horizontal portions of the floating gate material layer 42L that are in contact with the shallow trench isolation layer 20 (or the buried insulator layer if the semiconductor fins 30 are formed from an SOI substrate). If the floating gate material layer 42L is formed by a conformal deposition method, the thickness of vertical portions of the floating gate material layer 42L can be greater than the thickness of the topmost horizontal portions of the floating gate material layer 42L after formation of the semiconductor oxide portions 44.

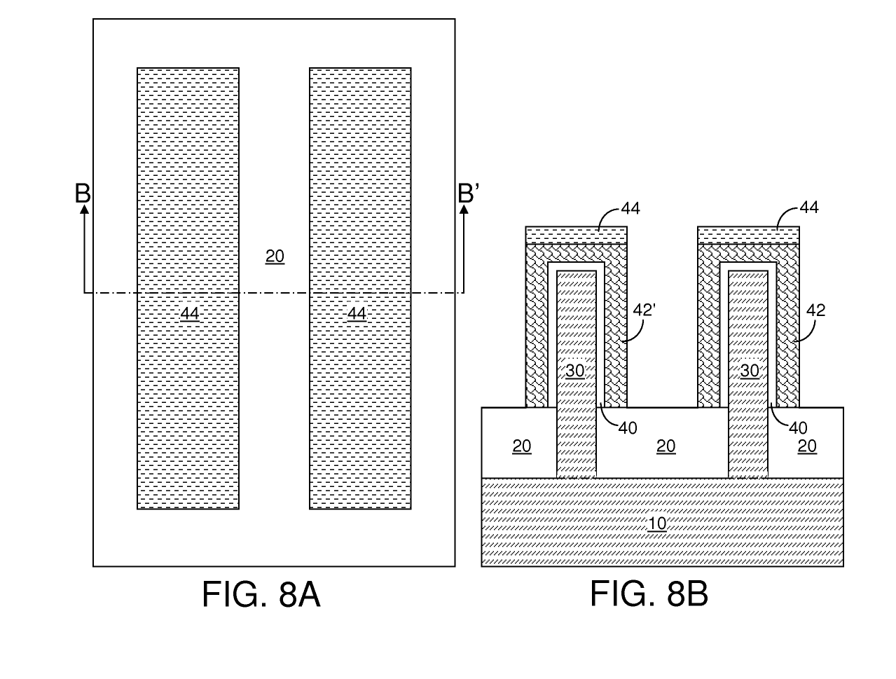

Referring to FIGS. 8A and 8B, the etch stop layer 46 can be removed by an isotropic etch selective to the semiconductor oxide portions 44 and the floating gate material layer 42L. If the etch stop layer 46 includes silicon nitride, the isotropic etch can be a wet etch employing hot phosphoric acid. Outer sidewall surfaces of vertical portions of the floating gate material layer 42L and top surfaces of horizontal portions of the floating gate material layer 42L are physically exposed after removal of the etch stop layer 46.

An anisotropic etch that is selective to the semiconductor oxide portions 44 is performed to remove horizontal portions of the floating gate material layer 42L that do not underlie the semiconductor oxide portions 44. As used herein, a first element underlies a second element if a topmost surface of the first element is not above a horizontal plane including a bottommost surface of the second element and if any area of the first element is within an area of the second element in a see-through top-down view. As used herein, a first element does not underlie a second element if a topmost surface of the first element is above a horizontal plane including a bottommost surface of the second element or if the entire area of the first element is outside an area of the second element in a see-through top-down view. As used herein, a see-through top-down view is a top-down view that is modified such that all intervening elements are treated as transparent elements.

The semiconductor oxide portions 44 are self-aligned to the areas of the topmost surfaces of the floating gate material layer 42L. In other words, the areas of the semiconductor oxide portions 44 coincide with the areas of the topmost surfaces of the floating gate material layer 42L. The semiconductor oxide portions 44 are employed as an etch mask during the anisotropic etch that removes the horizontal portions of the floating gate material layer 42L that do not underlie the semiconductor oxide portions 44. Each remaining portion of the floating gate material layer 42L constitutes a floating gate electrode 42. Thus, floating gate electrodes 42 are formed by patterning the floating gate material layer 42L employing the semiconductor oxide portions 44 as a self-aligned etch mask.

Each floating gate electrode 42 has an inverted U-shape, and can be formed on one of the inverted U-shaped tunneling gate dielectrics 40. The entirety of each outer sidewall of the floating gate electrodes 42 is within a single planar vertical plane, and extends from the topmost surface of the floating gate electrode 42 to the bottommost surface of the floating gate electrode 42. As used herein, a plane is “planar” if the plane is a two-dimensional Euclidean plane without any curvature.

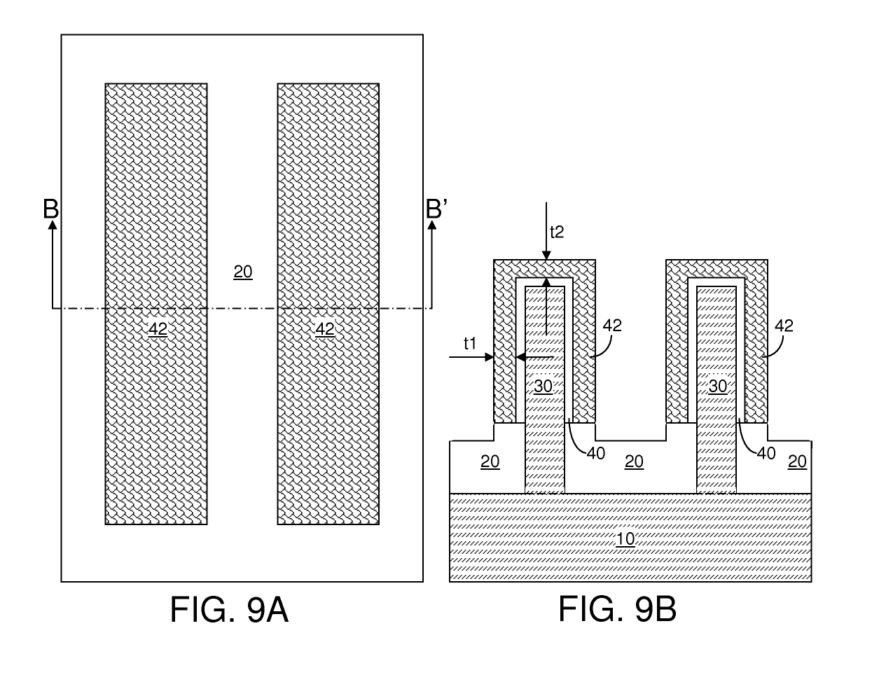

Referring to FIGS. 9A and 9B, the semiconductor oxide portions 44 are removed selective to the floating gate electrodes 42. In one embodiment, the semiconductor oxide portions 44 can be removed by an anisotropic etch such as a reactive ion etch. For example, if the semiconductor oxide portions 44 include silicon oxide, an oxide of a silicon-germanium alloy, or an oxide of a silicon-carbon alloy, the semiconductor oxide portions 44 can be removed by an anisotropic etch employing a hydrochlorocarbon etchant.

The thickness of vertical portions of each floating gate electrode 42 is herein referred to as a first thickness t1. The thickness of the horizontal portion of each floating gate electrode 42 is herein referred to as a second thickness t2. The first thickness t1 can be lesser than the second thickness t2 due to the consumption of the semiconductor material during formation of the semiconductor oxide portions 44 during the processing steps of FIGS. 7A and 7B.

If the shallow trench isolation layer 20 is a dielectric material layer, and can include silicon oxide, physically exposed top surfaces of the shallow trench isolation layer 20 can be collaterally recessed during the anisotropic etch. The sidewalls of the recessed portions of the shallow trench isolation layer 20 can be vertically coincident with sidewalls of the floating gate electrodes 42. As used herein, a first surface and a second surface are “vertically coincident” with each other if the first surface and the second surface coincide in a see-through top-down view. Vertically coincident surfaces are within the same vertical plane. In an embodiment in which a buried insulator layer of an SOI substrate is present underneath semiconductor fins, the buried insulator layer is a dielectric material layer, and physically exposed top surfaces of the buried insulator layer can be recessed during the anisotropic etch. In general, a dielectric material layer (which can be the shallow trench isolation layer 20 or a buried insulator layer derived from an SOI substrate) underlies each floating gate electrode 42, and the outer sidewalls of the floating gate electrodes 42 can be vertically coincident with vertical sidewalls of the dielectric material layer if an anisotropic etch is employed to remove the semiconductor oxide portions 44.

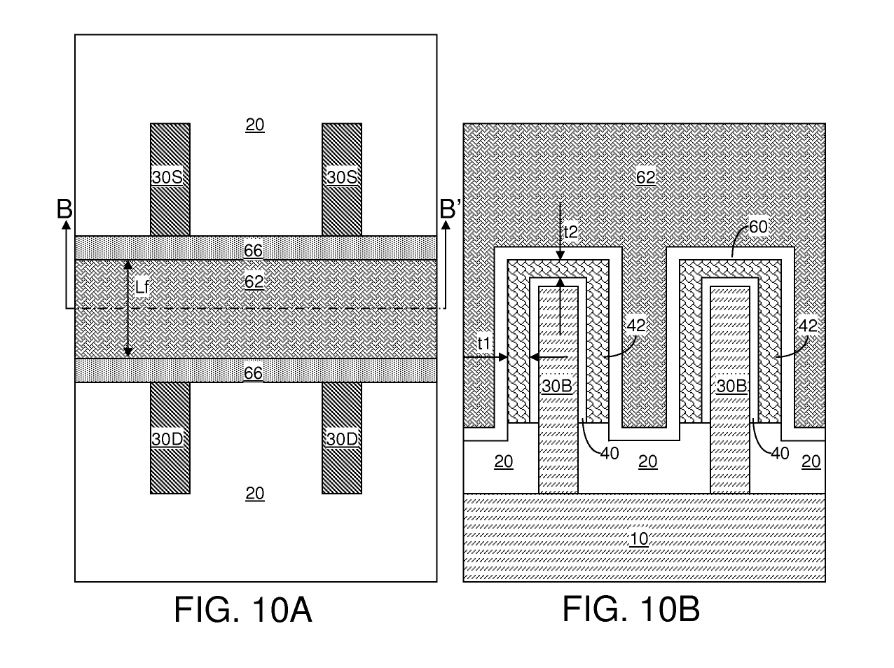

Referring to FIGS. 10A and 10B, a control gate dielectric layer including a dielectric material and a conductive material layer are sequentially deposited over the floating gate electrodes 42. The control gate dielectric layer can include any material for a gate dielectric as known in the art. For example, the control gate dielectric layer can include a dielectric oxide of a semiconductor material or at least one metal. The control gate dielectric layer can be formed by deposition of a dielectric material, and/or by conversion of surface portions of the floating gate electrodes 42. If any surface portions of the floating gate electrodes 42 are converted as a portion of the control gate dielectric layer, the decrease in thickness of the floating gate electrodes 42 can be uniform, and the remaining horizontal portions of the floating gate electrodes 42 can be thinner than the remaining vertical portions of the floating gate electrodes 42. The conductive material layer can include any conductive material that is suitable for a gate electrode as known in the art.

The stack of the conductive material layer and the control gate dielectric layer is patterned by a combination of lithographic methods and etch processes. For example, a photoresist layer (not shown) may be applied over the conductive material layer and lithographically patterned. Unmasked portions of the conductive material layer can be removed, for example, by an anisotropic etch that is selective to the material of the control gate dielectric layer. A remaining portion of the conductive material layer constitutes a control gate electrode 62. Unmasked portions of the control gate dielectric layer can be removed by an etch employing the photoresist layer as an etch mask. A remaining portion of the control gate dielectric layer constitutes a control gate dielectric 60. Thus, the control gate dielectric 60 is formed on the top surface and the outer sidewalls of each floating gate electrode 42, and the control gate electrode 62 is formed over the control gate dielectric 60.

Subsequently, unmasked portions of the floating gate electrodes 42 (i.e., portions of the floating gate electrodes 42 that do not underlie the photoresist layer) are removed by an etch. The removal of the unmasked portions of the floating gate electrodes 42 can be performed employing an anisotropic etch that is selective to the material of the tunneling gate dielectrics 40. Thus, portions of each floating gate electrode 42 that are not masked by the photoresist layer are removed by the anisotropic etch. Subsequently, portions of the floating gate dielectrics 40 that are not covered by the photoresist layer are removed by an etch that is selective to the semiconductor material of the semiconductor fins 30 (See FIGS. 9A and 9B). The etch can be an isotropic etch or an anisotropic etch.

A stack including a tunneling gate dielectric 40 and a floating gate electrode 42 is formed over each semiconductor fin 30. Each tunneling gate dielectric 40 and each floating gate electrode 42 can have the same length along the lengthwise direction of the semiconductor fins 30. The length of the tunneling gate dielectrics 40 and the floating gate electrodes 42 is herein referred to as the floating gate length Lf. A stack of a control gate dielectric 60 and a control gate electrode 62 overlies each stack of a tunneling gate dielectric 40 and a floating gate electrode 42. In one embodiment, the control gate dielectric 60 and the control gate electrode 62 can have the same length as at least one underlying stack including a tunneling gate dielectric 40 and a floating gate electrode 42, i.e., can have the same length as the floating gate length Lf.

In one embodiment, ion implantation of electrical dopants is performed employing the photoresist layer as an implantation mask. As used herein, electrical dopants refer to p-type dopants or n-type dopants. A source region 30S and a drain region 30D can be formed within regions of the semiconductor fins 30 that do not underlie the photoresist layer. The unimplanted portion of each semiconductor fin 30 constitutes a body region 30B. The photoresist layer can be removed after the ion implantation process, for example, by ashing. In another embodiment, ion implantation of electrical dopants can be performed after removal of the photoresist layer employing the floating gate electrode 62 as an implantation mask. Optionally, at least one gate spacer 66 can be formed by deposition of a conformal dielectric material layer and an anisotropic etch prior to, or after, the ion implantation process. Alternatively or additionally, source regions 30S and drain regions 30D can be formed by selective deposition of a doped semiconductor material such as selective epitaxy, and optionally by at least one ion implantation process.

The first exemplary semiconductor structure includes at least a semiconductor fin (30B, located on a substrate 10, an inverted U-shaped tunneling gate dielectric 40 located on the semiconductor fin 30, a floating gate electrode 42 having an inverted U-shape and contacting the inverted U-shaped tunneling gate dielectric 40, a control gate dielectric 60 contacting a top surface and outer sidewalls of the floating gate electrode 42, and a control gate electrode 62 overlying the control gate dielectric 60.

A dielectric material layer such as the shallow trench isolation layer 20 contacts at least one surface of the semiconductor fin 30, and underlies the inverted U-shaped tunneling gate dielectric 42 and the control gate electrode 62. Each outer sidewall of the floating gate electrode 42 adjoins a surface of the dielectric material layer. In one embodiment, the dielectric material layer is a shallow trench isolation layer 20 contacting lower portions of the outer sidewalls of the floating gate electrode 42.

A horizontal portion of each floating gate electrode 42 in contact with a topmost surface of an inverted U-shaped tunneling gate dielectric 40 has a lesser thickness (i.e., the second thickness t2) than a vertical portion of the floating gate electrode 42, which has the first thickness t1. In one embodiment, due to the recessing of top surfaces of the shallow trench isolation layer 20, a bottommost surface of the control gate dielectric 62 may be recessed relative to the bottommost surfaces of the floating gate electrodes 42.

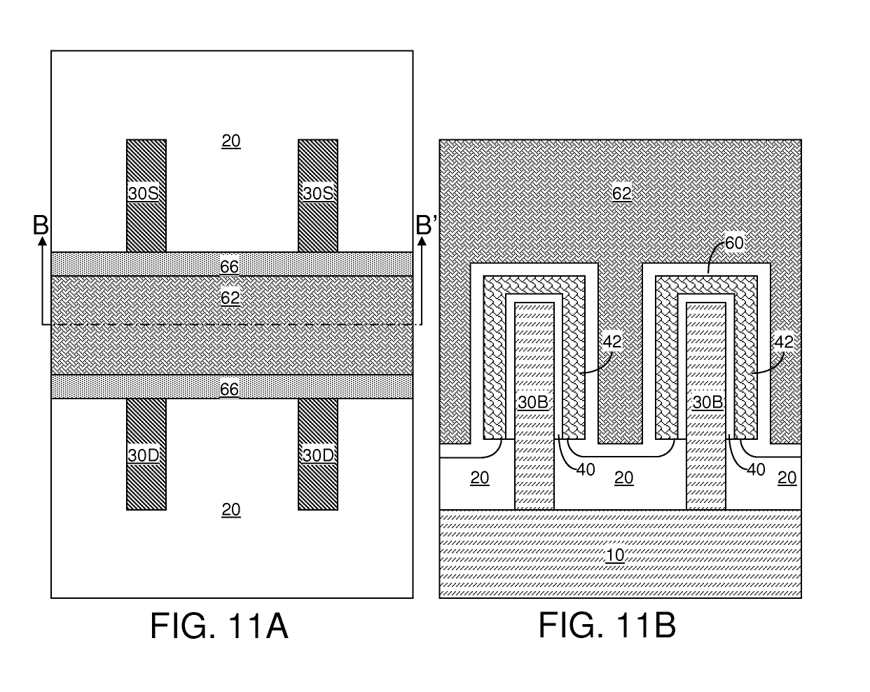

Referring to FIGS. 11A and 11B, a first variation of the first exemplary semiconductor structure can be derived from the first exemplary semiconductor structure of FIGS. 8A and 8B by employing an isotropic etch or a combination of an isotropic etch and an anisotropic etch to remove the semiconductor oxide portions 44. Subsequently, the processing steps of FIGS. 9A, 9B, 10A, and 10B are performed as described above.

In the first variation of the first exemplary semiconductor structure, a dielectric material layer (such as a shallow trench isolation layer 20) underlies each floating gate electrode 42. A portion of the control gate dielectric 60 is present in an undercut region of the dielectric material layer, and contacts a bottom surface of each floating gate electrode 42 and concave surfaces of the dielectric material layer (such as concave surfaces of a shallow trench isolation layer 20). If the semiconductor fins are formed from an SOI substrate, the dielectric material layer can be a buried insulator layer of the SOI substrate. In one embodiment, a bottommost surface of the control gate dielectric 62 may be recessed relative to the bottommost surfaces of the floating gate electrodes 42.

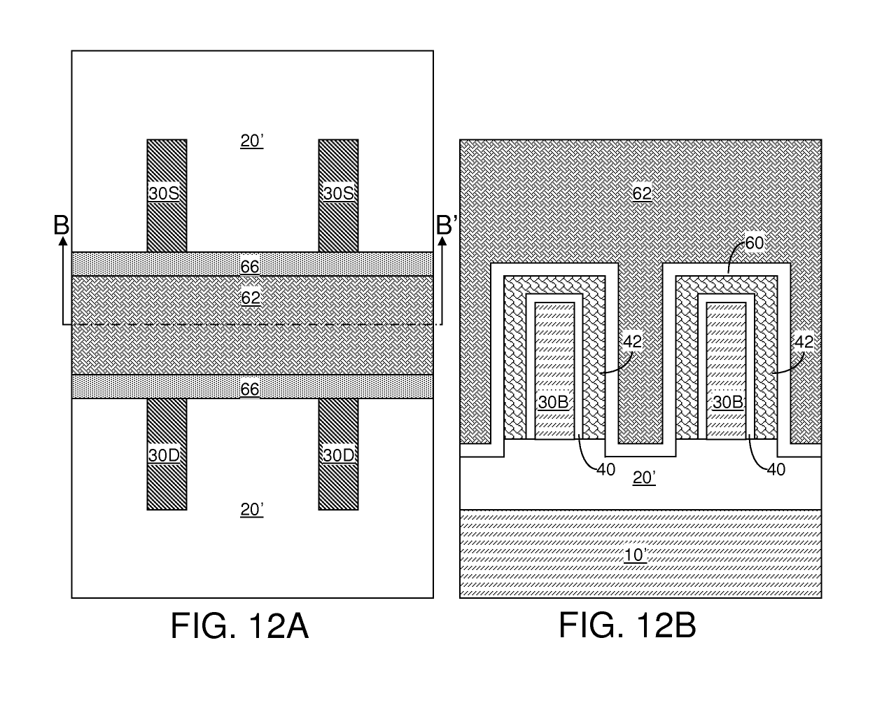

Referring to FIGS. 12A and 12B, a second variation of the first exemplary semiconductor structure can be derived from the first exemplary semiconductor structure or the first variation thereof by employing an SOI substrate in lieu of a bulk semiconductor substrate. In this case, the semiconductor fins 30 (See FIGS. 1A and 1B) can be formed by patterning the top semiconductor layer of the SOI substrate, and the dielectric material layer underlying the floating gate electrodes 42 can be the insulator layer 20′ provided as a buried insulator layer within the SOI substrate. The insulator layer 20′ contacts the top surface of a handle substrate 10′ within the substrate (10′. 20′), and contacts the bottom surface of each semiconductor fin (30S, 30D, 30B).

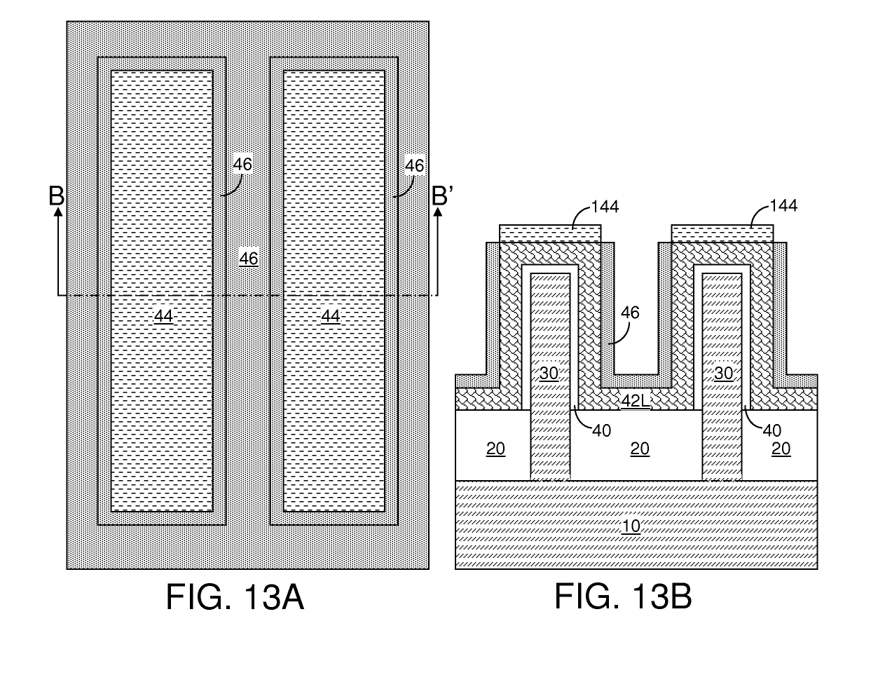

Referring to FIGS. 13A and 13B, a second exemplary semiconductor structure according to the first embodiment of the present disclosure can be derived from the first exemplary semiconductor structure of FIGS. 6A and 6B or variations thereof by forming semiconductor oxide portions 44 by selective deposition of a semiconductor oxide material. During the selective deposition of the semiconductor oxide material, the semiconductor oxide material is deposited only on semiconductor surfaces, and is not deposited on dielectric surfaces or metallic surfaces. The semiconductor oxide portions 44 can be formed, for example, by selective deposition of silicon oxide by a liquid phase deposition process. Selective deposition of silicon oxide by liquid phase deposition is described, for example, in Hsu et al., “Growth and Electrical Characteristics of Liquid-Phase Deposited SiO₂ on Ge,” Electrochem. Solid-State Lett. 2003 6(2): F9-F11 and U.S. Pat. No. 6,004,886.

Subsequently, the processing steps of FIGS. 8A and 8B are performed. After removal of the etch mask layer 46, the semiconductor oxide portions 44 formed over the floating gate material layer 42L are employed as an etch mask during an anisotropic etch process. Each remaining portion of the floating gate material layer 42L after performing an anisotropic etch is a floating gate electrode 42.

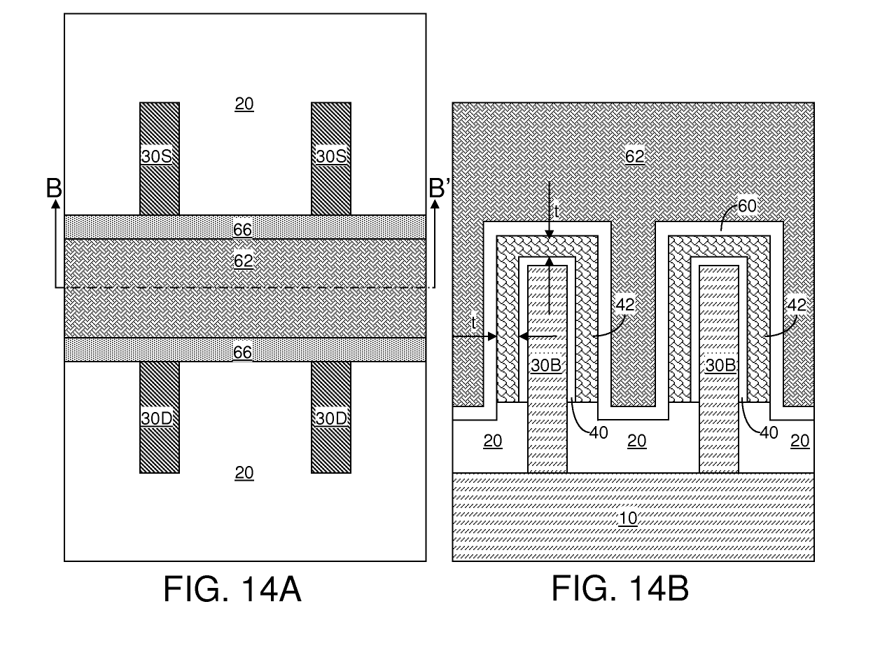

Referring to FIGS. 14A and 14B, the processing steps of FIGS. 9A, 9B, 10A, and 10B are subsequently performed. If the floating gate material layer 42L is formed by a conformal deposition process such as low pressure chemical vapor deposition (LPCVD) process or an atomic layer deposition (ALD) process, the horizontal portion of each floating gate electrode 42 in contact with a topmost surface of the inverted U-shaped tunneling gate dielectric 40 can have the same thickness t as the vertical portions of the floating gate electrode 42.

While the present disclosure has been described in terms of specific embodiments, it is evident in view of the foregoing description that numerous alternatives, modifications and variations will be apparent to those skilled in the art. Each of the various embodiments of the present disclosure can be implemented alone, or in combination with any other embodiments of the present disclosure unless expressly disclosed otherwise or otherwise impossible as would be known to one of ordinary skill in the art. Accordingly, the present disclosure is intended to encompass all such alternatives, modifications and variations which fall within the scope and spirit of the present disclosure and the following claims.

What is claimed is:

1. A semiconductor structure comprising:
a semiconductor fin located on a substrate;
an inverted U-shaped tunneling gate dielectric located on said semiconductor fin and having a same thickness throughout;
a floating gate electrode having an inverted U-shape and contacting said inverted U-shaped tunneling gate dielectric;
a control gate dielectric contacting a top surface and outer sidewalls of said floating gate electrode; and
a control gate electrode overlying said control gate dielectric.

2. The semiconductor structure of claim 1, wherein an entirety of each outer sidewall of said floating gate electrode is within a vertical plane and extends from a topmost surface of said floating gate electrode to a bottommost surface of said floating gate electrode.

3. The semiconductor structure of claim 1, further comprising a dielectric material layer contacting at least one surface of said semiconductor fin and underlying said inverted U-shaped tunneling gate dielectric and said control gate electrode.

4. The semiconductor structure of claim 3, wherein each outer sidewall of said floating gate electrode adjoins a surface of said dielectric material layer.

5. The semiconductor structure of claim 3, wherein said dielectric material layer is a shallow trench isolation layer contacting lower portions of said outer sidewalls of said floating gate electrode.

6. The semiconductor structure of claim 3, wherein said dielectric material layer is an insulator layer contacting a top surface of a handle substrate within said substrate and a bottom surface of said semiconductor fin.

7. The semiconductor structure of claim 1, wherein a horizontal portion of said floating gate electrode in contact with a topmost surface of said inverted U-shaped tunneling gate dielectric has a lesser thickness than a vertical portion of said floating gate electrode.

8. The semiconductor structure of claim 1, wherein a horizontal portion of said floating gate electrode in contact with a topmost surface of said inverted U-shaped tunneling gate dielectric has the same thickness as a vertical portion of said floating gate electrode.

9. The semiconductor structure of claim 1, wherein a bottommost surface of said control gate dielectric is recessed relative to a bottommost surface of said floating gate electrode.

10. The semiconductor structure of claim 9, further comprising a dielectric material layer underlying said floating gate electrode, wherein said outer sidewalls of said floating gate electrode are vertically coincident with vertical sidewalls of said dielectric material layer.

11. The semiconductor structure of claim 9, further comprising a dielectric material layer underlying said floating gate electrode, wherein a portion of said control gate dielectric in an undercut region of said dielectric material layer contacts a bottom surface of said floating gate electrode and concave surfaces of said dielectric material layer.

12. A method of forming a semiconductor structure comprising:
forming a semiconductor fin on a substrate;
forming an inverted U-shaped tunneling gate dielectric on said semiconductor fin;
forming a floating gate electrode having an inverted U-shape on said inverted U-shaped tunneling gate dielectric;
forming a control gate dielectric on a top surface and outer sidewalls of said floating gate electrode; and
forming a control gate electrode over said control gate dielectric.

13. The method of claim 12, wherein said floating gate electrode is formed by:
forming a floating gate material layer over said inverted U-shaped tunneling gate dielectric; and
patterning said floating gate material layer employing an etch mask that is self-aligned to an area of a topmost surface of said floating gate material layer.

14. The method of claim 13, wherein said etch mask is a semiconductor oxide portion formed over said floating gate material layer, and said floating gate electrode is a remaining portion of said floating gate material layer after performing an anisotropic etch employing said etch mask.

15. The method of claim 14, wherein said semiconductor oxide portion is formed by oxidation of a semiconductor material in said floating gate material layer while sidewall surfaces of said floating gate material layer are protected by an oxygen-impermeable material.

16. The method of claim 14, wherein said semiconductor oxide portion is formed by selective deposition of silicon oxide by a liquid phase deposition process.

17. The method of claim 13, further comprising:
forming an etch stop layer over said floating gate material layer; and
physically exposing a topmost surface of said floating gate material layer by removing a horizontal portion of said etch stop layer overlying said topmost surface of said floating gate material layer.

18. The method of claim 17, further comprising:
depositing a dielectric material over said etch stop layer; and
planarizing said dielectric material layer employing said horizontal portion of said etch stop layer as a stopping layer, wherein a planarization dielectric layer is formed.

19. The method of claim 13, wherein said floating gate electrode layer is formed on a top surface of a dielectric material layer contacting a surface of said semiconductor fin, and wherein an entirety of each outer sidewall of said floating gate electrode is within a vertical plane and extends from a topmost surface of said floating gate electrode to a bottommost surface of said floating gate electrode.

20. The method of claim 19, further comprising removing said etch mask selective to said floating gate electrode, wherein a portion of said dielectric material layer is recessed during removal of said etch mask.
